(19) United States
(12) Patent Application Publication
(10) Pub. No.: US 2026/0150179 A1
(43) Pub. Date: May 28, 2026

(54) SYSTEM AND METHOD FOR RESONATOR TUNING USING VARIABLE CAPACITOR

(71) Applicant: Applied Materials, Inc., Santa Clara, CA (US)

(72) Inventors: Benjamin Alexandrovich, Brookline, MA (US); Peter F. Kurunczi, Cambridge, MA (US); Scott E. Peitzsch, Tewksbury, MA (US); Luke Bonecutter, Cedar Park, TX (US); Krag R. Senior, Austin, TX (US); Jonathan Daniel Moore, Georgetown, TX (US); David T. Blahnik, Round Rock, TX (US); Maximilian Schneider, Boston, MA (US); Michael C. Simmons, Austin, TX (US)

(73) Assignee: Applied Materials, Inc., Santa Clara, CA (US)

(21) Appl. No.: 18/957,147

(22) Filed: Nov. 22, 2024

(51) Int. Cl. H05H 7/02; H01J 37/08; H01J 37/317; H05H 9/04

(52) U.S. Cl. CPC H05H 7/02; H01J 37/08; H01J 37/3171; H05H 9/04; H01J 2237/0473; H05H 2007/025

(57) ABSTRACT

An ion implanter is provided, including an ion source and extraction system, arranged to generate a continuous ion beam at a first ion energy, and a linear accelerator, arranged to generate a bunched ion beam from the continuous ion beam, and to accelerate the bunched ion beam to a second ion energy, greater than the first ion energy. As such, the linear accelerator may include a plurality of acceleration stages, where a given acceleration stage of the linear accelerator includes a drift tube assembly, arranged to accelerate the bunched ion beam through a plurality of acceleration gaps. The given acceleration stage may also include a resonator, arranged to deliver an RF voltage signal to the drift tube assembly, and a resonance control circuit, having a variable capacitor that is arranged to adjust a resonator capacitance of the resonator, in order to maintain a resonant frequency of the resonator circuit.

### FIELD OF THE DISCLOSURE

The disclosure relates generally to ion implantation apparatus and more particularly to high energy beamline ion implanters based upon RF linear accelerators.

### BACKGROUND OF THE DISCLOSURE

Ion implantation is a process of introducing dopants or impurities into a substrate via bombardment. Ion implantation systems may comprise an ion source and a series of beam-line components. The ion source may comprise a chamber where ions are generated. The ion source may also comprise a power source and an extraction electrode assembly disposed near the chamber. The beam-line components, may include, for example, a mass analyzer, a first acceleration or deceleration stage, a collimator, and a second acceleration or deceleration stage. Much like a series of optical lenses for manipulating a light beam, the beam-line components can filter, focus, and manipulate ions or ion beam having particular species, shape, energy, and/or other qualities. The ion beam passes through the beam-line components and may be directed toward a substrate mounted on a platen or clamp.

Implantation apparatus capable of generating ion energies of approximately 1 MeV or greater are often referred to as high energy ion implanters, or high energy ion implantation systems. One type of high energy ion implanter employs a so-called tandem acceleration architecture where ions are accelerated through a first column to high energy, undergo charge exchange to change polarity, and then are accelerated to a second energy, approximately double the first energy in a second column. Another type of high energy ion implanter is termed a linear accelerator, or LINAC, where a series of electrodes arranged as tubes conduct and accelerate the ion beam to increasingly higher energy along the succession of tubes, where the electrodes receive an AC voltage signal. Standard LINACs are driven by a 13.56 MHz signal using a resonator circuit including coil and capacitor. Overall, standard LINACs employing 13.56 MHz resonators employ many accelerator stages and accordingly many resonators to accelerate an initially low energy ion beam to a target ion energy.

Acceleration of ions in an RF-LINAC takes place by conducting packetized ‘bunches’ of ions through a series of powered hollow electrodes, which electrodes may be referred to as “drift tubes.” An RF signal applied by a resonator assembly to a powered drift tube causes the potential at a given powered drift tube to vary in a regular periodic manner, according to the amplitude of the voltage from the RF signal. Ideally, as an ion bunch emerges from a given drift tube, the instantaneous potential at the given drift tube will be such that the potential difference between the given drift tube and a downstream drift tube, adjacent to the given drift tube, will be at a maximum. Thus, the emerging ion bunch will experience a maximum accelerating field across a gap between the given electrode and the downstream electrode. This occurrence of the maximum accelerating field may generally correspond to the instant when the RF voltage reaches a maximum potential. Accordingly, the length of the drift tubes within a given LINAC are constructed so that ion bunches generally experience a high accelerating field when emerging from a given drift tube.

To operate efficiently and generate a relatively higher RF voltage amplitude given an RF input, a resonator assembly is provided with a resonator coil as part of a resonance circuit to deliver a peak RF voltage at the end of the resonator coil that is connected to a powered drift tube. The resonator may be described as having an resonator coil that acts as an inductor, being disposed within a grounded conductive enclosure (i.e.) “a resonator can”). The proximity of the resonator can to the resonator coil creates a distributed capacitance. The inductor (resonator coil) together with the capacitance of the resonator can forms a parallel LC circuit (i.e. an LC tank circuit) having a resonant frequency is 1/2π\sqrt{LC}.

In known systems, the resonance circuit is tuned so that the system maintains resonance at a resonant frequency that lies at or near the frequency of the incoming RF signal from an RF source. Moreover, the resonant frequency of each resonator corresponding to the different acceleration stages of a linear accelerator is to be maintained at the same frequency so that relative phase of RF voltage signals delivered at different resonators can be properly set and maintained. In operation, the inductance of a resonator coil or capacitance of the resonator may change, due to mechanical, thermal, or other changes within the resonator. To maintain proper resonance, in known systems, movable parts have been provided within the resonator enclosure, so as to slightly adjust the inductance or capacitance in the resonator, and adjust the resonant frequency accordingly.

Note that such systems, having movable parts within a resonator enclosure, may engender certain problems, including wear and tear of movable parts, susceptibility to mechanical vibration, and so forth.

With respect to these and other considerations, the present disclosure is provided.

### BRIEF SUMMARY

In one embodiment, an ion implanter is provided. The ion implanter ma include an ion source and extraction system, arranged to generate a continuous ion beam at a first ion energy, and a linear accelerator, arranged to generate a bunched ion beam from the continuous ion beam, and to accelerate the bunched ion beam to a second ion energy, greater than the first ion energy. As such, the linear accelerator may include a plurality of acceleration stages, where a given acceleration stage of the linear accelerator includes a drift tube assembly, arranged to accelerate the bunched ion beam through a plurality of acceleration gaps. The given acceleration stage may also include a resonator, arranged to deliver an RF voltage signal to the drift tube assembly, and a resonance control circuit, having a variable capacitor that is arranged to adjust a resonator capacitance of the resonator, in order to maintain a resonant frequency of the resonator circuit.

In another embodiment, a method of operating an ion implanter is provided. The method may include accelerating a bunched ion beam through a plurality of acceleration stages in a linear accelerator of the ion implanter, and performing a sense measurement in a resonator of a given acceleration stage of the linear accelerator, while the bunched ion beam is transported through the linear accelerator. The method may include outputting a sense value based upon the sense measurement to a phase module, determining if a resonance condition in the resonator is met, based upon the sense value; and sending a control signal to adjust a capacitance in the resonator, when the resonance condition is not met.

### BRIEF DESCRIPTION OF THE DRAWINGS

FIG. 1A shows an exemplary ion implantation system, according to embodiments of the disclosure;

FIG. 1B shows an exemplary acceleration stage of a linear accelerator;

FIG. 2A illustrates one exemplary architecture for resonance control;

FIG. 2B illustrates another exemplary architecture for resonance control;

FIG. 3A shows a tilted end view of a variable capacitor;

FIG. 3B shows a side cross-sectional view of a variable capacitor;

FIG. 4A is a graph depicting capacitance as a function of turns in a variable capacitor;

FIG. 4B is a graph depicting resonant frequency and reflected power as a function of variable capacitor capacitance in a resonator arranged according to embodiments of the disclosure;

FIG. 5 depicts a resonator assembly including a resonance control circuit according to embodiments of the disclosure;

FIG. 6 depicts an exemplary process flow according to some embodiments of the disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for improved linear accelerator control, and improved high energy ion implantation systems, based upon a beamline architecture using a linear accelerator (LINAC). For brevity, an ion implantation system may also be referred to herein as an “ion implanter.” Various embodiments provide novel configurations for providing the capability of generating high energy ions, where the final ion energy delivered to a substrate may be 300 keV, 500 keV, 1 MeV or greater. In exemplary embodiments, a novel resonance circuit arrangement and techniques are provided for monitoring and maintaining resonance in acceleration stages of RF LINACs.

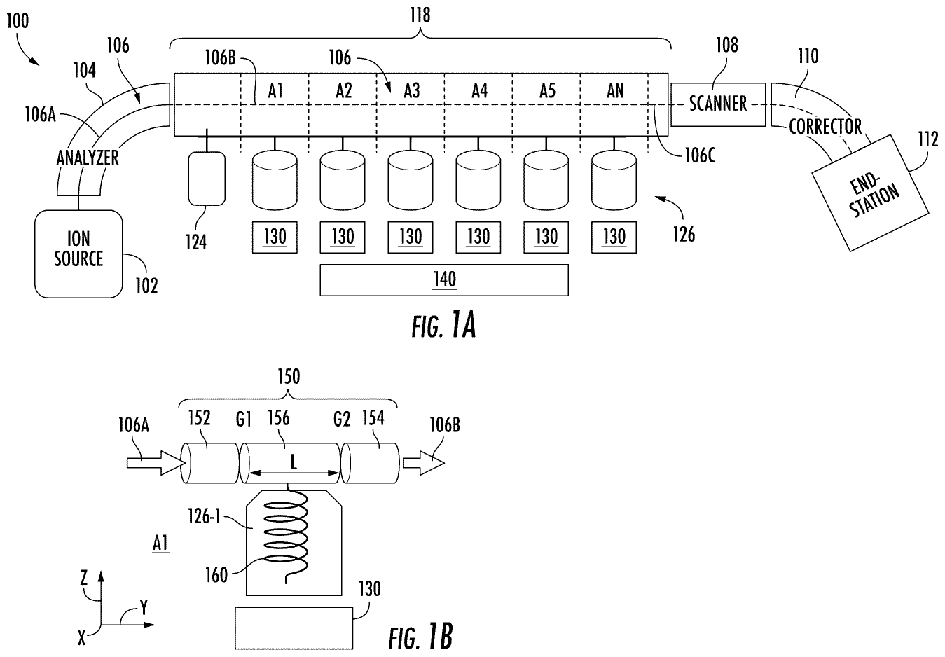

FIG. 1A depicts a schematic of an ion implanter apparatus, according to embodiments of the disclosure. The ion implanter 100, may represent a beamline ion implanter, with some elements not shown for clarity of explanation. The ion implanter 100 may include an ion source 102, as known in the art. The ion source 102 may include an extraction system including extraction components and filters (not shown) to generate an ion beam 106 at a first energy. Examples of suitable ion energy for the first ion energy range from 5 keV to 300 keV, while the embodiments are not limited in this context. To form a high energy ion beam, the ion implanter 100 may include various additional components for accelerating the ion beam 106. As output by the ion source 102, the ion beam may be a continuous ion beam 106A.

The ion implanter 100 may include an analyzer 104, functioning to analyze the ion beam 106 as in known apparatus, by changing the trajectory of the ion beam 106, as shown. The ion implanter 100 may also include a buncher 124, which component may form an upstream part of an RF linear accelerator, shown as LINAC 118. The buncher 124 may be arranged as in known apparatus to output the continuous ion beam 106A as a bunched ion beam 106B. The LINAC 118 may include various acceleration stages to accelerate the bunched ion beam 106B by application of an RF signal at the different stages. The LINAC may output the bunched ion beam 106B as a high energy ion beam 106C. The ion implanter 100 may include various additional components, such as a scanner 108, to scan the high energy ion beam 106C, such as in a transverse direction to a direction of propagation of the high energy ion beam 106C. The ion implanter may further include components such as a corrector 110 and end station 112, as known in the art.

To impart a target final energy to the high energy ion beam 106C, the LINAC 118 may include a series of RF assemblies, where a given RF assembly is arranged to deliver a given RF signal to a given acceleration stage of the LINAC 118. The different acceleration stages of LINAC 118 are identified as acceleration stage A1, acceleration stage A2, acceleration stage A3, acceleration stage A4, acceleration stage A5, and acceleration stage AN. However, according to other embodiments, the LINAC 188 may have fewer acceleration stages or a greater number of acceleration stages, where the acceleration stage AN may represent the last, most downstream acceleration stage that outputs the high energy ion beam 106C at a highest beam energy. A given acceleration stage of the acceleration stages of LINAC 118 may be coupled to a dedicated RF assembly that includes an RF power source (not separately shown) that generates an RF signal to power the given acceleration stage. The RF signal is fed to a resonator circuit, or “resonator,” which circuit couples an RF voltage to an electrode in the given acceleration stage, as detailed with respect to FIG. 1B. These resonator circuits are designated as resonators 126 in FIG. 1A. As the bunched ion beam 106B passes through successive acceleration stages of the LINAC 118, the bunched ion beam 106B will be accelerated to a high energy, based upon the number of acceleration stages and the amplitude of the RF voltage applied by a given resonator 126 at each acceleration stage.

To illustrate how energy is coupled into a bunched ion beam, FIG. 1B depicts details of an exemplary acceleration stage, shown as acceleration stage A1, which stage may be representative of any of the acceleration stages (A1-AN) shown in FIG. 1A. The acceleration stage A1 may include a drift tube assembly 150, as well as a resonator 126-1. In various non-limiting embodiments the drift tube assembly 150 may be a double gap configuration or a triple gap configuration. The configuration explicitly shown in FIG. 1B is a double gap configuration. In this arrangement, the drift tube assembly 150 includes a first grounded drift tube 152, a second grounded drift tube 154, and a powered drift tube 156. As suggested, the first grounded drift tube 152 and the second grounded drift tube 156 may be coupled to ground potential. The powered drift tube 156 is coupled to a resonator coil 160 that delivers an RF voltage signal, which RF voltage signal causes an RF field to develop in the gap G1 between the first grounded drift tube 152 and the powered drift tube 156, as well as an RF field in the gap G2 between the powered drift tube 156 and the second grounded drift tube 154. The timing of the phase of an RF signal as applied to the powered drift tube 156 will affect how an ion bunch that passes through gap G1 or gap G2 is accelerated by the acceleration stage.

Referring again to FIG. 1A, in order to properly maintain the resonators 126 in a resonance condition, the ion implanter 100 may include a set of resonance control circuits, shown as resonance control circuit 130, where a given resonance control circuit ma be dedicated to a given resonator, as shown. In brief, resonance control circuit 130 is operable to dynamically adjust capacitance in a given resonator, as detailed hereinbelow, in a manner to maintain operation at a resonant condition.

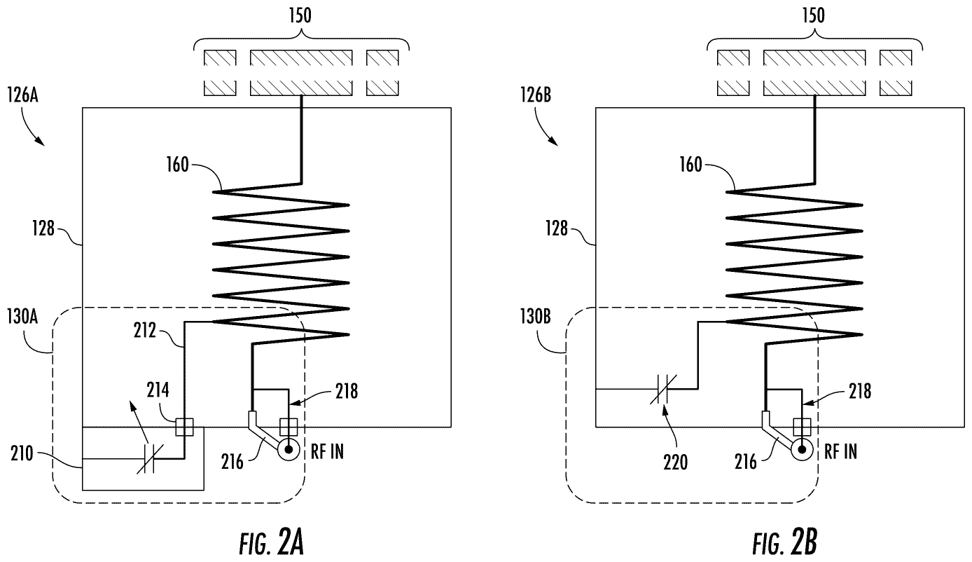

FIG. 2A illustrates one exemplary architecture for resonance control. As discussed previously, the resonator coil 160 is coupled to deliver a high voltage RF signal form power input 216 to a powered electrode of the drift tube assembly 150. In this embodiment a resonance control circuit 130A is provided that couples to the resonator coil 160. The resonance control circuit 130A is useful to control capacitance of the resonator circuit formed by the resonator 126A by adjusting capacitance of the resonator circuit, in particular by dynamically adjusting capacitance, and thus adjusting the frequency of the resonator 126.

By way of explanation, a resonant network is created by the distributed inductance of the resonator coil 160 and a distributed capacitance of the resonator coil 160 to the resonator enclosure 128. This inductance together with the capacitance creates an LC tank circuit with the resonant frequency f₀, where

$${f}_{0} = \frac{1}{2 π \sqrt{LC}} . \qquad ( 1 )$$

The initial geometry of the resonator enclosure 128 and the inductor (resonator coil 160) are modeled and chosen so that the resonant frequency is ideally the same as the operating frequency of the linear accelerator, which frequency may be set at the nominal frequency of RF power source, such as 13.56 MHz.

In real RF LINACs though, the resonant frequency is not always the same as the desired operating frequency. For example, deviation of the resonant frequency may occur due to manufacturing tolerances affecting the pitch of the resonator coil 160, and the exact shaping of the different windings of the resonator coil 160. Also, during operation under high power RF, the temperature of the resonator coil 160 and resonator enclosure 128 will increase, resulting in thermal expansion of the resonator coil and resonator enclosure 128. This expansion changes the overall inductance and capacitance of the system and accordingly changes the resonant frequency.

The present embodiments address the above issue by providing a resonance control circuit, such as resonance control circuit 130A to dynamically adjust capacitance to the resonator circuit formed by resonator 126A, and thus adjust the resonant frequency. In particular, a variable capacitor 210 is provided to connect to the resonator coil 160. Adjusting the variable capacitance upwardly or downwardly in the variable capacitor 210 will then add or subtract capacitance to the resonator circuit, resulting in the tuning of the resonant frequency in accordance with Eq. (1). The term “variable capacitor” as used herein may refer to a capacitor having a capacitance that can be adjusted controllably and reversibly.

In this embodiment, the variable capacitor 210 is disposed outside of the resonator enclosure 128, and is coupled to the resonator coil 160, through a feedthrough 214. In this embodiment, the variable capacitor 210 is directly electrically connected to a low voltage winding of the resonator coil 160, meaning a winding at the RF input side of the resonator coil 160.

According to various embodiments of the disclosure, the variable capacitor 210 or similar variable capacitors of the present embodiments may be a commercially available motorized capacitor that provides high reliability and durability associated with motorized capacitors. Examples of such capacitors include RF matching network equipment used in commercial RF power supplies used for semiconductor processing equipment. As such, the variable capacitor 210 may be an off-the-shelf part that exhibits low loss and provides a wide capacitance tuning range as well as very fine control of capacitance.

FIG. 2B illustrates another exemplary architecture for resonance control. In this embodiment, features of the resonator 126B may be similar to the features of resonator 126A, with like components labeled the same. A difference in this embodiment is where a resonance control circuit 130B is provided with a variable capacitor 220 positioned inside of the resonator enclosure 128. An advantage of this configuration is the avoidance of the need for a high voltage RF feedthrough, as is needed when a variable capacitor is mounted outside of the resonator enclosure 128. Moreover, electromagnetic interference may be reduced.

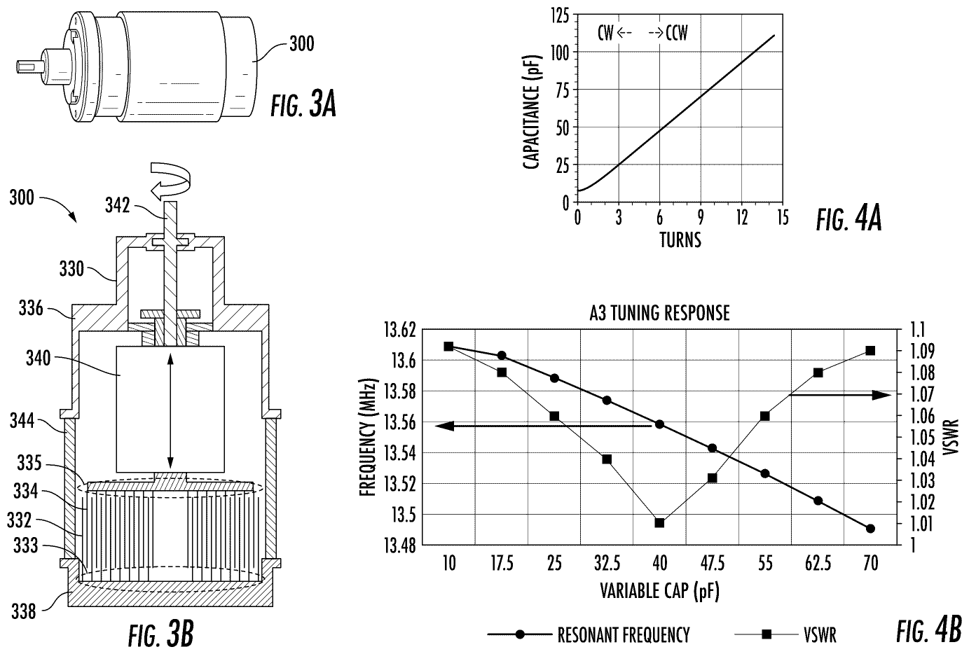

FIG. 3A shows a tilted end view of a variable capacitor 300. FIG. 3B shows a side cross-sectional view of a variant of the variable capacitor 300. In this embodiment, the variable capacitor 300 is defined by a top electrical connection 336 and bottom electrical connection 338. These electrical connections are isolated from one another by insulator housing 344. The capacitance of the variable capacitor 300 is imparted by interdigitated electrode structures shown as bottom electrode portions 332 and top electrode portions 334. In some embodiments, the bottom electrode portions may form a first set of plates and the top electrode portions 334 may form a second set of plates. The bottom electrode portions 332 form a single electrode, shown as bottom electrode 333, and the top electrode portions 334 form another single electrode, shown as top electrode 335, where the capacitance of the variable capacitor 300 is defined by the separation and overlap in area between adjacent ones of bottom electrode portions 332 and top electrode portions 334. In some embodiments, the variable capacitor 300 may withstand voltages as high as 10 kV or larger between electrodes, making the variable capacitor 300 suitable for connection to a resonator coil in a RF LINAC, where maximum voltage amplitude may reach 100 kV or higher.

In order to vary the capacitance, the variable capacitor 300 is provided with a movable part 340, attached to the top electrode 335, so that the top electrode 335 may be moved with respect to the bottom electrode 333. In this manner, the overlap of the bottom electrode portion with the top electrode portion is changed, thus changing the effective area of the variable capacitor 300, and the capacitance, accordingly. In some embodiments The movement of movable part 340 may be provided by a rotating part 342 that forms part of a motorized component.

FIG. 4A is a graph depicting capacitance as a function of turns in a variable capacitor. In this example, capacitance is adjusted as discussed with respect to FIG. 3B. Over 15 turns, the capacitance may be adjusted from 10 pF to 125 pF. Capacitance is increased in a linear fashion with each turn by approximately 7.5 pF.

FIG. 4B is a graph presenting experimental data depicting resonant frequency and voltage standing wave ratio (VSWR) as a function of variable capacitor capacitance in a resonator equipped with a resonant control circuit arranged according to embodiments of the disclosure. The resonator is for an acceleration stage A3 of a linear accelerator. Again, the capacitance of the resonator is varied by rotating a rotatable spindle in a variable capacitor, to generate a relative displacement of capacitor electrodes with respect to one another. The range of capacitance for FIG. 4B from 10 pF to 70 pF corresponds to 8 turns of a variable capacitor in one example. As shown in the FIG. 4B, the voltage standing wave ratio (VSWR) may be minimized toward a value of 1 at a capacitance of 40 pF, which value lies in the middle of the capacitance range shown. This reflected power corresponds to a resonant frequency of the resonator circuit of 13.56 MHz, matching the nominal frequency of the RF power supply.

As illustrated in FIG. 4B, the total change in resonant frequency over the range of capacitance measured is 120 kHz, achieved by rotation across 8 turns of the variable capacitor range. Thus, the resonance control circuit of this embodiment generates a change of resonant frequency of the resonator ˜15 kz per turn. Note that in this embodiment the variable capacitor is driven by a motor encoder equipped with on the order of 8 million counts per revolution. Thus, a given step of the motor provides a very fine resolution of ˜0.002 Hertz of frequency tuning per step, so that the resonant frequency may be selected to a precision of well less than 1 Hz out of an absolute frequency of ˜13 MHz.

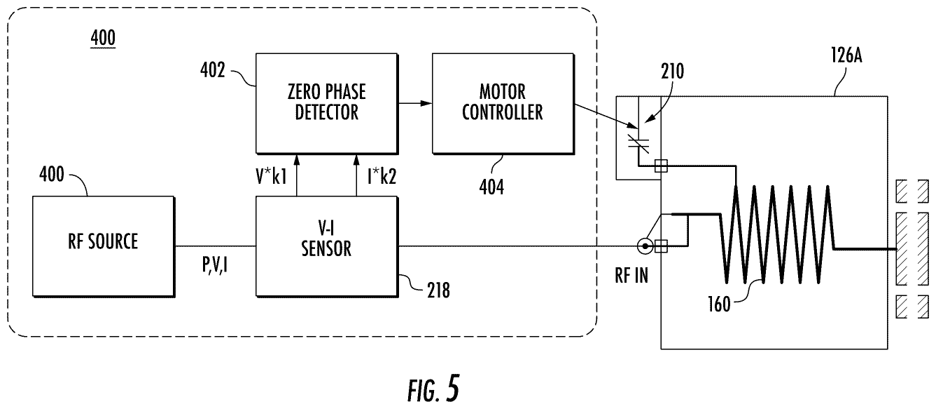

In various embodiments of the disclosure, the resonant frequency of a resonator for an RF LINAC may be automatically controlled. FIG. 5 depicts a resonator assembly including a resonance control circuit 400 according to embodiments of the disclosure. In this example, resonance frequency is controlled in a closed loop fashion. The architecture of FIG. 5A depicts components of the resonance control circuit 130A, but may apply equally to resonance control circuit 130B. The resonance control circuit 400 adds components to provide automatic tuning of the resonator 126A, including a voltage-current (V-I) sensor 218, coupled to the resonator coil 160. The resonance control circuit 400 further includes a phase detector 402, coupled to receive a current reading and a voltage reading from the V-I sensor 218, and a motor controller 404, coupled to receive an output from the phase detector 402, and to generate a control signal for the variable capacitor 210.

In various embodiments, the resonance control circuit 400 is furnished with a control algorithm that is based on the premise that at resonance the RF input voltage and current are in phase. The V-I sensor 218 output signals are proportionally scaled down from the input V and I. This arrangement ensures stable phase shift between the signals. In operation, the phase detector 402 may output an error signal indicative of the phase offset between RF input voltage and current. The error signal output is received by the motor controller 404 to adjust a motorized capacitor, such as variable capacitor 210. Thus, the output error signal may cause the motor controller 404 to rotate the variable capacitor motor in one direction of the other, to increase or decrease capacitance, depending on the error signal.

In other embodiments, an open loop control may be provided where a phase detector is arranged for auto-zeroing, or where measured RF reflected power is minimized. Moreover, motor control of a motorized capacitor may be optimized by selecting a velocity control mode of operation. In some embodiments, a lossless V-I sensor may be provided, with a fixed (power independent) output phase, such as close to 90°.

In the aforementioned embodiments, adjustment of a resonator circuit to maintain the resonator frequency at a targeted value is generally disclosed with respect to a given acceleration stage. In additional embodiments, a similar resonance control circuit architecture may be provided across each of the acceleration stages of a linear accelerator so that the resonant frequency of all the resonators is the same as a master clock that controls the entire LINAC.

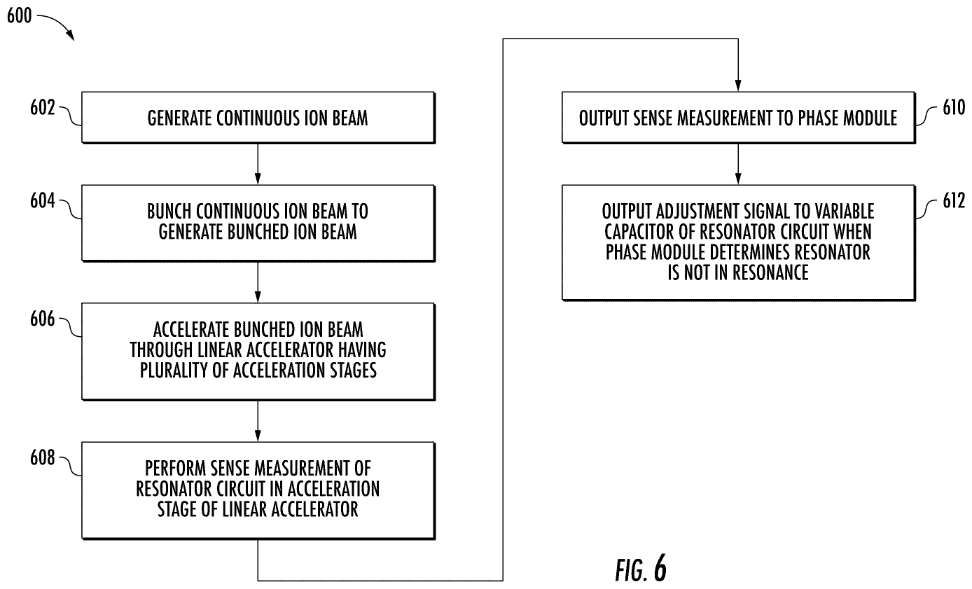

FIG. 6 depicts an exemplary process flow 600, according to some embodiments of the disclosure. At block 602, a continuous ion beam is generated. At block 604 the continuous ion beam is bunched into a bunched ion beam. The bunched ion beam may be bunched using a buncher that forms an upstream part of an RF linear accelerator.

At block 606, the bunched ion beam is accelerated through a linear accelerator. The linear accelerator may include a plurality of acceleration stages that are driven by dedicated RF assemblies, including dedicated resonators that are designed to resonate at the frequency of the RF power signal supplied by an RF power source. Thus, in a given acceleration stage, a given resonator may be coupled to a given RF power source to deliver RF voltage to a given drift tube assembly of the given acceleration stage.

At block 608, during the operation of the RF linear accelerator, when a bunched ion beam is accelerated therethrough, a sense measurement may be performed of the resonator circuit formed by the given resonator of the given acceleration stage. In particular, embodiments a sense measurement may be performed by a V-I sensor connected to a resonator coil of the resonator to perform the V-I measurement. In other embodiments, a sense measurement may be performed by a pickup loop that may be coupled via electromagnetic coupling to a resonator coil, for example.

At block 610 the V-I measurement, such as a set of V-I values, is output from the V-I sensor to a phase module. The outputs of the V-I sensor may be received at the phase module as input voltage sense and input current sense inputs.

At block 612, an adjustment signal is output to a variable capacitor that is part of the resonator circuit of the resonator. In various embodiments, an analog signal may be output to a motor controller where the strength of the analog signal is proportional to the phase difference between V and I signals received from the V-I sensor. For example, the phase module may output a command signal, such as a voltage, to a controller for the variable capacitor. In particular embodiments, the controller for the variable capacitor may be a motor controller for a motorized capacitor that adjusts the capacitance by relative motion of one capacitor electrode with respect to another capacitor electrode.

In various embodiments, the adjustment of the capacitance of the variable capacitor may be performed in a closed loop fashion, where zero motion of the motorized capacitor is commanded when zero phase offset is measured between V output and I output of the V-I sensor. In particular embodiments of velocity control, the commanded motor velocity of a motorized capacitor may be set at zero RPM when a zero phase offset is measured by the output of the V-I sensor.

In view of the foregoing, at least the following advantages are achieved by the present embodiments. In a first advantage, the motorized capacitors of the present embodiments provide reliability and durability for directly tuning a resonator circuit. The present embodiments provide the further advantage of a low cost solution, such as using off-the-shelf capacitors, having superior properties, including low loss and very fine tuning control over a wide tuning range. In embodiments where the capacitor in mounted internally in a resonator enclosure, the further advantages include removing of the need for an HV RF feedthrough, as well as electromagnetic interference reduction by enclosing high RF voltage and current.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An ion implanter, comprising:
an ion source and extraction system, arranged to generate a continuous ion beam at a first ion energy; and
a linear accelerator, the linear accelerator being arranged to generate a bunched ion beam from the continuous ion beam, and to accelerate the bunched ion beam to a second ion energy, greater than the first ion energy, wherein the linear accelerator comprises a plurality of acceleration stages, wherein a given acceleration stage of the linear accelerator comprises:
a drift tube assembly, arranged to accelerate the bunched ion beam through a plurality of acceleration gaps;
a resonator, arranged to deliver an RF voltage signal to the drift tube assembly; and
a resonance control circuit, having a variable capacitor that is arranged to adjust a resonator capacitance of the resonator, in order to maintain a resonant frequency of the resonator.

2. The ion implanter of claim 1, wherein the resonator comprises a resonator enclosure, wherein the variable capacitor is disposed in the resonator enclosure.

3. The ion implanter of claim 1,
wherein the resonator comprises a resonator enclosure, wherein the variable capacitor is disposed outside of the resonator enclosure.

4. The ion implanter of claim 1,
wherein the resonator comprises a resonator enclosure, and a resonator coil, disposed within the resonator enclosure, and wherein the resonance control circuit further comprises:
a voltage-current (V-I) sensor, coupled to the resonator coil.

5. The ion implanter of claim 4,
wherein the resonance control circuit further comprises:
a phase detector, coupled to receive a current reading and a voltage reading from the V-I sensor; and
a motor controller, coupled to receive an output from the phase detector, and to generate a control signal for the variable capacitor.

6. The ion implanter of claim 1, wherein the variable capacitor comprises a first set of plates and a second set of plates, wherein the first set of plates are movable with respect to the second set of plates, so as to adjust a capacitance of the variable capacitor.

7. The ion implanter of claim 4, wherein the variable capacitor is directly connected to a low voltage winding of the resonator coil.

8. The ion implanter of claim 1, wherein the plurality of acceleration stages each comprise:
a resonance control circuit, having a variable capacitor that is arranged to adjust a resonator capacitance of the resonator.

9. The ion implanter of claim 1,
wherein the resonator comprises a resonator enclosure, and a resonator coil, disposed within the resonator enclosure, and wherein the resonance control circuit further comprises:
a pickup loop, coupled to the resonator coil.

10. A method of operating an ion implanter, comprising:
accelerating a bunched ion beam through a plurality of acceleration stages in a linear accelerator of the ion implanter;
performing a sense measurement in a resonator of a given acceleration stage of the linear accelerator, while the bunched ion beam is transported through the linear accelerator;
outputting a sense value based upon the sense measurement to a phase module;
determining if a resonance condition in the resonator is met, based upon the sense value; and
sending a control signal to adjust a capacitance in the resonator, when the resonance condition is not met.

11. The method of claim 10,
wherein the performing the sense measurement comprises performing a V-I measurement in the resonator, and
wherein the sense value is a set of V-I values based upon the V-I measurement.

12. The method of claim 10, wherein the resonator comprises a variable capacitor that is arranged to adjust a resonator capacitance of the resonator, in order to maintain a resonant frequency of the resonator.

13. The method of claim 12, wherein the resonator comprises a resonator enclosure, wherein the variable capacitor is disposed in the resonator enclosure.

14. The ion implanter of claim 12,
wherein the resonator comprises a resonator enclosure, wherein the variable capacitor is disposed outside of the resonator enclosure.

15. The method of claim 10,
wherein the resonator comprises a resonator enclosure, and a resonator coil, disposed within the resonator enclosure, and wherein the sense measurement is performed by a voltage-current (V-I) sensor, coupled to the resonator coil.

16. The method of claim 12,
wherein the control signal is sent to a motor controller, coupled to adjust a capacitance of the variable capacitor.

17. The method of claim 16, wherein the variable capacitor comprises a first set of plates and a second set of plates, wherein the motor controller is configured to move the first set of plates with respect to the second set of plates, so as to adjust a capacitance of the variable capacitor.
